(19) United States
(12) Patent Application Publication
(10) Pub. No.: US 2026/0341328 A1
(43) Pub. Date: Oct. 29, 2026

(54) APPARATUSES AND METHODS FOR REFRESHING MEMORY ARRAYS

(71) Applicant: Micron Technology, Inc., Boise, ID (US)

(72) Inventors: Joseph Riad, College Station, TX (US); Yang Lu, Boise, ID (US)

(73) Assignee: Micron Technology, Inc., Boise, ID (US)

(21) Appl. No.: 19/192,013

(22) Filed: Apr. 28, 2025

(51) Int. Cl. G11C 11/406

(52) U.S. Cl. CPC G11C 11/406

(57) ABSTRACT

A memory device may include bank increment counters (BICs) associated with individual banks. The bank increment counters may indicate a relative offset/count increment from a global counter for automatic refresh addresses. Refresh logic may combine the values of the BICs with the value of the global counter to generate a refresh address for a bank. This may cause a bank to refresh a row different than a row indicated by the global counter. In some examples, count logic may use information from the BICs to determine when to increment the global counter.

### BACKGROUND

A dynamic random access memory (DRAM), which may be a semiconductor memory device, stores information by charges accumulated in cell capacitors (e.g., memory cells) that gradually discharge. Thus, the information may be lost unless refresh operations are periodically carried out. Refresh commands are periodically issued from an external device, such as a memory controller, to cause the memory to perform refresh operations. The refresh commands should be issued at a frequency that ensures refresh operations are performed at a frequency sufficient to preserve the data in the memory cells. Timing of refresh operations performed by a memory device is specified by a refresh interval time (tREFI). As memory arrays become denser, more refresh commands may be required. Accordingly, efficient execution of refresh operations are desired.

### BRIEF DESCRIPTION OF THE DRAWINGS

Embodiments of the present disclosure will be described in detail with reference to accompanying drawings.

FIG. 1 is a timing diagram illustrating an approach to incrementing a CBR counter compliant with DDR5 standards and specifications.

FIG. 2 is a timing diagram illustrating an approach to incrementing a CBR counter compliant with LPDDR5 standards and specifications.

FIG. 3 is a block diagram of a system according to at least one embodiment of the disclosure.

FIG. 4 is a block diagram of a semiconductor memory device according at least one embodiment of the disclosure.

FIG. 5 shows block diagrams of a memory device illustrating behavior of a bank increment counter according to at least one embodiment of the disclosure.

FIG. 6 is a block diagram of count logic according to at least one embodiment of the disclosure.

FIG. 7 is a block diagram of count logic according to at least one embodiment of the disclosure.

FIG. 8 is a block diagram of count logic and a CBR counter according to at least one embodiment of the disclosure.

FIG. 9 is a block diagram of at least a portion of a memory device according at least one embodiment of the disclosure.

FIG. 10 is a block diagram of at least a portion of a memory device according at least one embodiment of the disclosure.

FIG. 11 is a flow chart of a method according to at least one embodiment of the disclosure.

### DETAILED DESCRIPTION

Memory arrays in DRAM may be organized into different portions referred to as banks. The banks may be organized into groups referred to as bank groups. A bank group may include one or more banks, and the memory array may include one or more bank groups (e.g., four bank groups each including four banks). In certain DRAM memory types such as DDR5 and LPDDR5, some specifications and/or standards (e.g., JEDEC) require that all memory banks in a bank group are refreshed during a same bank refresh (REFsb) or a per bank (REFpb) before the global refresh counter can be incremented. The global refresh counter may be referred to as a CAS before RAS (CBR) refresh counter.

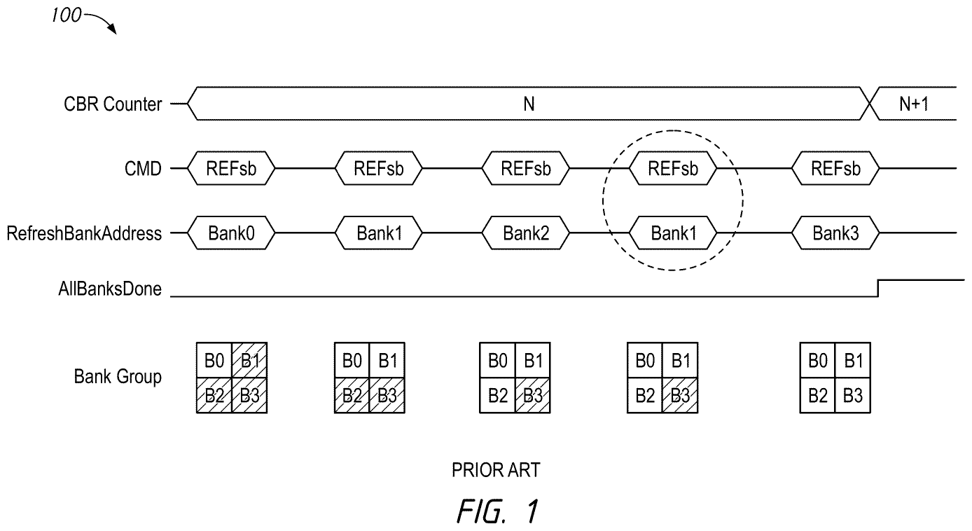

FIG. 1 is a timing diagram illustrating an approach to incrementing a CBR counter compliant with DDR5 standards and specifications. The timing diagram 100 illustrates a process of refreshing banks of a bank group. In the example shown, the bank group has four banks (B0-3). In DDR5, the CBR counter only increments after all banks in a bank group have been refreshed. As shown in timing diagram 100, the CBR counter is initially at a value of N. A series of refresh commands (REFsb) and associated bank addresses (BANK0-3) for a bank group are issued by a controller to a memory device. As illustrated by the shading in the bank group, after the first command, row N of B0 is refreshed, and after the second command, row N of B1 is refreshed, and after the third command, row N of B2 is refreshed.

The controller then issues a fourth refresh command for B1. Because the CBR counter has not incremented, the same row of B1 is refreshed again. It is not until the controller issues a fifth refresh command for B3 that the CBR counter increments to N+1 and a different row of the banks of the bank group can be refreshed. Thus, unless there was an exceptional circumstance where row N of B1 required an additional refresh, the additional refresh command for B1 was unnecessary and caused a refresh to be “wasted.” This may increase the time required to completely refresh the banks of the bank group.

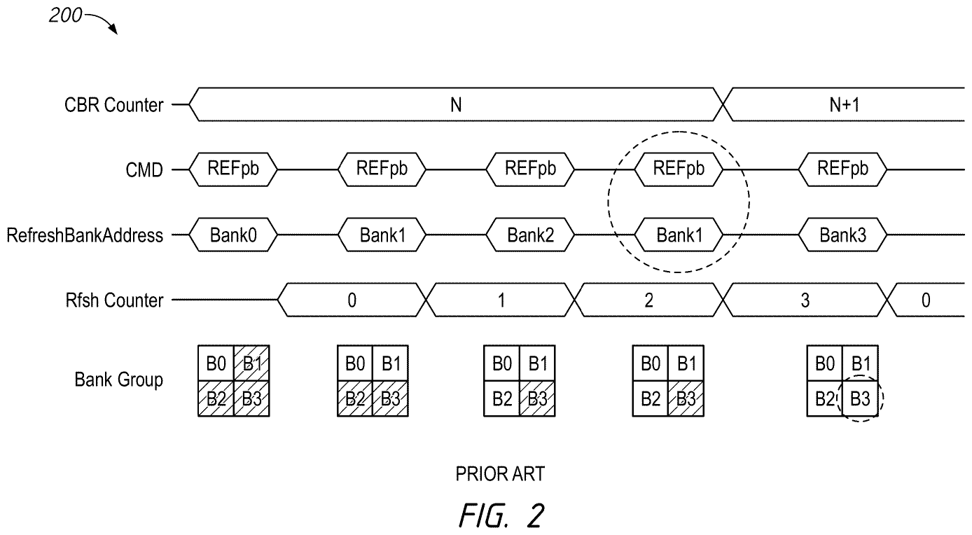

FIG. 2 is a timing diagram illustrating an approach to incrementing a CBR counter compliant with LPDDR5 standards and specifications. The timing diagram 200 illustrates a process of refreshing banks of a bank group. In the example shown, the bank group has four banks (B0-3). In LPDDR5, the CBR counter increments after M refresh commands have been received. In the example shown, M=4. As shown in timing diagram 200, the CBR counter is initially at a value of N. A series of refresh commands (REFpb) and associated bank addresses (BANK0-3) for a bank group are issued by a controller to a memory device. As illustrated by the shading in the bank group, after the first command, row N of B0 is refreshed, and after the second command, row N of B1 is refreshed, and after the third command, row N of B2 is refreshed.

As in FIG. 1, the controller then issues a fourth refresh command for B1. Because the CBR counter has not incremented, the same row of B1 is refreshed again. However, after the fourth refresh command, M has been met, so the CBR counter increments to N+1. When the controller issues a fifth refresh command for B3, B3 is refreshed, but row N+1 is refreshed, not row N. Thus B3 missed a refresh of row N, and data in that row may be vulnerable to loss. Thus, the burden is on the controller to avoid issuing refresh commands to banks that have already been refreshed to avoid missing refreshing rows in certain banks. While some LPDDR5 devices have mechanisms for ignoring extra refresh commands to a same bank in a bank group to avoid prematurely incrementing the CBR counter, these devices have the issue of wasted refresh commands similar to DDR5 devices.

Both DDR5 and LPDDR5 devices require refresh operations to be delayed if a bank is performing an access operation (e.g., read or write command). Since all banks are required to be in sync in regards to the row address they're refreshing, this prevents other banks from refreshing even if those banks are not currently performing any active operations.

According to embodiments of the present disclosure, memory devices may include circuits that allow banks of a bank group to refresh out of sync. The circuits may allow for banks to refresh a different row if an extra refresh command is provided and/or prevent rows from being skipped by a refresh operation. In some embodiments, each bank may be associated with a bank increment counter (BIC) to keep track of the bank's refresh address (RXADD) increment relative to the (global) CBR counter. In some embodiments, pairs of banks or bank groups may share a BIC. The BIC may keep track of how many refreshes each bank or bank group is out-of-sync with the CBR counter. A circuit may receive signals from the BIC to determine when the CBR counter should be incremented in some embodiments. Allowing the banks to refresh out of sync may reduce “wasted” refresh commands and/or reduce the risk of skipping rows during refresh operations.

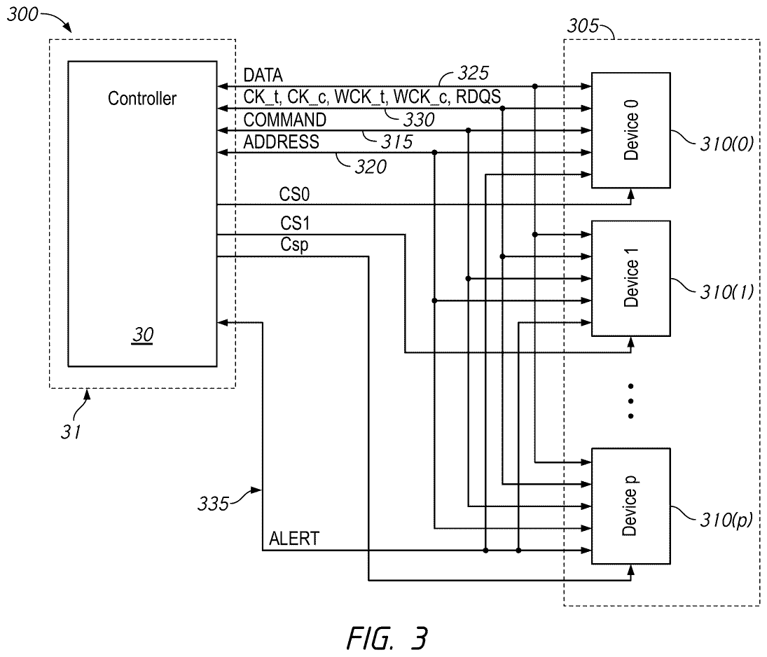

FIG. 3 is a block diagram of a system according to at least one embodiment of the disclosure. The system 300 includes a controller 30 and a memory system 305. In some embodiments, the controller may be included in a host device 31. The host device 31 may further include a processor and/or a computing system (not shown) in some embodiments. The memory system 305 includes memories 310(0)-310(p) (e.g., “Device 0 ” through “Device p”), where p is a non-zero whole number. However, in some embodiments, memory system 305 may include a single memory 310 (e.g., memory 310(0)). The memories 310(0)-310(p) may each include a memory array (not shown in FIG. 3) of memory cells for storing data. The memories 310(0)-310(p) are each coupled to command, address, data, clock, and alert busses. In some embodiments of the disclosure the memories 310(0)-310(p) are organized as ranks of memory. In such embodiments, the memories may be accessed by the ranks of memory. The controller 30 and the memory system 305 are in communication over several busses. For example, commands and addresses are received by the memory system 305 on a command bus 315 and an address bus 320, respectively, and data is provided between the controller 30 and the memory system 305 over a data bus 325. Various clock signals may be provided between the controller and memory system 305 over a clock bus 330. The clock bus 330 may include signal lines for providing system clock signals CK_t and CK_c received by the memory system 305, data clock signals WCK_t, and WCK_c received by the memory system 305, and optionally, an access data clock signal RDQS provided by the memory system 305 to the controller 30. Various alerts, some of which will be described herein, may be provided by the memory system 305 to the controller 30 on alert bus 335. Each of the busses may include one or more signal lines on which signals are provided.

The CK_t and CK_c signals provided by the controller 30 to the memory system 305 are used for timing the provision and receipt of the commands and addresses. The WCK_t and WCK_c signals and the RDQS signal are used for timing the provision of data. The CK_t and CK_c signals are complementary and the WCK_t and WCK_c signals are complementary. Clock signals are complementary when a rising edge of a first clock signal occurs at the same time as a falling edge of a second clock signal, and when a rising edge of the second clock signal occurs at the same time as a falling edge of the first clock signal.

The controller 30 provides commands to the memory system 305 to perform memory operations. Non-limiting examples of memory commands include timing commands for controlling the timing of various operations, access commands for accessing the memory, such as read commands for performing read operations and write commands for performing write operations, refresh commands for refreshing memory cells of memory arrays, mode register write and read commands for performing mode register write and read operations, as well as other commands and operations. The command signals provided by the controller 30 to the memory system 305 further include select signals (e.g., chip select CS signals CS0, CS1, CSp). While all of the memories 310 are provided the commands, addresses, data, and clock signals, the select signals provided on respective select signal lines are used to select which one or more of the memories 310 will respond to the command and perform the corresponding operation. In some embodiments of the disclosure, a respective select signal is provided to each memory 310 of the memory system 305. The controller 30 provides an active select signal to select the corresponding memory 310. While the respective select signal is active, the corresponding memory 310 is selected to receive to the commands and addresses provided on the command and address busses 315 and 320.

In operation, the controller 30 may provide refresh commands on the command bus 315 to the memories 310(0)-310(p) along with activating the appropriate select signal(s) in order to cause the selected memories 310(0)-110(p) to perform refresh operations to refresh data stored in the corresponding memory arrays. The refresh commands may be issued by the controller 30 may be interspersed with other commands, such as read and write commands, at regular or irregular intervals. Optionally, the controller 30 may also issue a command to cause the selected memories 310(0)-110(p) to enter a self-refresh mode which causes the selected memories 310(0)-310(p) to perform periodic refresh operations without additional refresh commands received from the controller 30 until the controller 30 issues a subsequent command to exit the self-refresh mode.

Various aspects of the interactions between the controller 30 and memory system 305 may be defined by a standard. If controller 30 provides inputs complying with the standard, the memory system 305 performs operations and/or provides outputs complying with the standard in a properly operating system 300. Compliance with the standard may allow controllers and memories to act in a predictable manner. For example, compliance may help ensure the proper data is written to the memories 310(0)-310(p) and the proper data is read from the memories 310(0)-310(p). Timing requirements for the controller 30 issuing refresh commands to the memories 310(0)-310(p) of the memory system 305 (e.g., tREFI, tREFP) may be defined by a standard. Compliance with these refresh parameters may ensure the integrity of the data stored in the memories 310(0)-310(p).

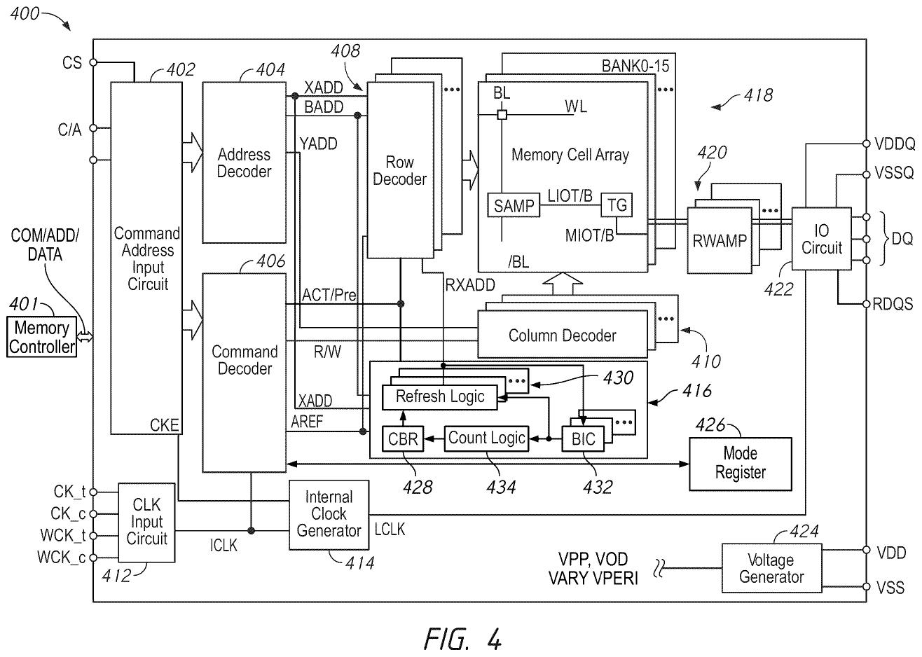

FIG. 4 is a block diagram of a semiconductor memory device according at least one embodiment of the disclosure. The memory device 400 may be as a DRAM device integrated on a single semiconductor chip. For context, a memory controller 401 is also shown. In some embodiments, device 400 may be included in one or more of memories 310(0)-310(p). In some embodiments, controller 401 may be included in controller 30.

The memory device 400 includes a memory array 418. The memory array 418 is shown as including a plurality of memory banks. In the embodiment of FIG. 4, the memory array 418 is shown as including sixteen memory banks BANK0-BANK15. More or fewer banks may be included in the memory array 418 of other embodiments. The banks may be organized into bank groups. For example, BANK0-3 may form a first bank group, BANK4-7 may form a second bank group, BANK8-11 may form a third bank group, and BANK12-15 may form a fourth bank group. Other arrangements of the bank group may be possible (e.g., two bank groups each including eight banks, eight bank groups each including two banks).

Each memory bank includes a plurality of word lines WL, a plurality of bit lines BL and/BL, and a plurality of memory cells MC arranged at intersections of the plurality of word lines WL and the plurality of bit lines BL and/BL. The selection of the word line WL is performed by a row decoder circuit 408 and the selection of the bit lines BL and/BL is performed by a column decoder circuit 410. In the embodiment of FIG. 4, the row decoder circuit 408 includes a respective row decoder circuit for each memory bank and the column decoder circuit 410 includes a respective column decoder for each memory bank. The bit lines BL and/BL are coupled to a respective sense amplifier (SAMP). Read data from the bit line BL or/BL is amplified by the sense amplifier SAMP, and transferred to read/write amplifiers 420 over complementary local data lines (LIOT/B), transfer gate (TG), and complementary main data lines (MIOT/B). Conversely, write data outputted from the read/write amplifiers 420 is transferred to the sense amplifier SAMP over the complementary main data lines MIOT/B, the transfer gate TG, and the complementary local data lines LIOT/B, and written in the memory cell MC coupled to the bit line BL or/BL.

The memory device 400 may employ a plurality of external terminals that include command and address (C/A) terminals coupled to a command and address bus to receive commands and addresses, and a CS signal, clock terminals to receive clocks CK_t CK_c, WCK_t, and WCK_c to provide data clock RDQS, data terminals DQ to provide data, and power supply terminals to receive power supply potentials VDD, VSS, VDDQ, and VSSQ.

The clock terminals are supplied with external clocks CK_t, CK_c, WCK_t, and WCK_c that are provided to an input circuit 412. The external clocks may be complementary. The input circuit 412 generates internal clock signals based on the internal clock signals such as internal clock ICLK based on the CK_t and CK_c clocks. The ICLK clock is provided to the command decoder circuit 410 and to an internal clock generator 414. The internal clock generator 414 provides various internal clocks LCLK based on the ICLK clock. The LCLK clocks may be used for timing operation of various internal circuits. The internal data clocks LCLK are provided to the input/output circuit 422 to time operation of circuits included in the input/output circuit 422, for example, to data receivers to time the receipt of write data.

The C/A terminals may be supplied with memory addresses. The memory addresses supplied to the C/A terminals are transferred, via a command/address input circuit 402, to an address decoder 404. The address decoder 404 receives the address and supplies a decoded row address XADD to the row decoder circuit 408 and supplies a decoded column address YADD to the column decoder circuit 410. The address decoder 404 may also supply a decoded bank address BADD, which may indicate the bank of the memory array 418 containing the decoded row address XADD and column address YADD. The C/A terminals may be supplied with commands. Examples of commands include access commands for accessing the memory, such as commands for performing read operations and commands for performing write operations. Other examples of commands include mode register read and write commands, which may be used to read and write data from a mode register 426. The access commands may be associated with one or more of a row address XADD, column address YADD, and/or bank address BADD to indicate the memory cell(s) to be accessed. In some embodiments, the commands and/or addresses may be provided by a component external to the device 400, for example, as shown in FIG. 4, a memory controller 401 in communication with the device 400.

The commands may be provided as internal command signals to a command decoder circuit 406 via the command/address input circuit 402. The command decoder circuit 406 includes circuits to decode the internal command signals to generate various internal signals and commands for performing operations. For example, the command decoder circuit 406 may provide a row command signal ACT to select a word line and a column command signal R/W to select a bit line.

The device 400 may receive a command for writing one or more values to a mode register 426. The values in the mode register 426 may define modes of operation of the device 400. For example, the values in the mode register 426 may indicate burst length, frequency, CAS latency, enablement of write data copy operations, etc. In some embodiments, the memory controller 401 may provide the mode register write command and an address provided with the mode register write command may indicate a register within the mode register 426 to be written to and the value to be written to the register. In some embodiments, such as the one shown in FIG. 4, the command decoder circuit 406 may write the value to the indicated register of the mode register 426. In other embodiments, the address decoder circuit 404 may provide the value to be written to the mode register 426. In other embodiments, the command address input circuit 402 may write the value to the indicated register of the mode register 426.

The device 400 may receive access commands for performing read operations. When the commands are received, and a bank address, a row address and a column address are timely supplied with the commands, read data is read from memory cells in the memory array 418 corresponding to the row address and column address. The commands are received by the command decoder circuit 406, which provides internal commands so that read data from the memory array 418 is provided to the read/write amplifiers 420. The read data is output to outside from the data terminals DQ via the input/output circuit 422.

The device 400 may receive access commands for performing write operations. When the commands are received, and a bank address, a row address and a column address are timely supplied with the commands, write data supplied to the data terminals DQ is written to a memory cells in the memory array 418 corresponding to the row address and column address. The commands are received by the command decoder circuit 406, which provides internal commands so that the write data is received by data receivers in the input/output circuit 422. The write data is supplied via the input/output circuit 422 to the read/write amplifiers 420, and by the read/write amplifiers 420 to the memory array 418 to be written into the memory cell MC.

The power supply terminals are supplied with power supply potentials VDD and VSS. The power supply potentials VDD and VSS are supplied to an internal voltage generator circuit 424. The internal voltage generator circuit 424 generates various internal potentials VPP, VOD, VARY, VPERI, and the like based on the power supply potentials VDD and VSS supplied to the power supply terminals. The internal potential VPP is mainly used in the row decoder circuit 408, the internal potentials VOD and VARY are mainly used in the sense amplifiers SAMP included in the memory array 418, and the internal potential VPERI is used in many peripheral circuit blocks.

The power supply terminals are also supplied with power supply potentials VDDQ and VSSQ. The power supply potentials VDDQ and VSSQ are supplied to the input/output circuit 422. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 422 so that power supply noise generated by the input/output circuit 422 does not propagate to the other circuit blocks.

In some embodiments, the memory controller 401 may be in communication with a processor, such as a central processing unit of a computing system (not shown). In other embodiments, the memory controller 401 may be integrated with the processor. The memory controller 401 may provide commands COM and/or addresses ADD to the C/A terminals of the device 400 and provide and receive data DATA via the DQ terminals of the device 400. In some embodiments, some of the commands and/or addresses provided by the memory controller 401 may be based on instructions provided by the processor. Some of the instructions provided by the processor may be based, at in part, on a program being executed by the processor (e.g., executable instructions stored on a non-transitory computer readable medium accessible to the processor, not shown). Some of the commands provided by the memory controller 401 may be generated internally by circuitry of the memory controller 401.

The device 400 may receive commands from the memory controller 401 causing it to carry out one or more refresh operations responsive to refresh commands. The refresh signal AREF may be a pulse signal which is activated when the command decoder circuit 406 receives a signal which indicates a refresh command or an entry to the self-refresh mode. The refresh signal AREF may be activated once immediately after command input. In self-refresh mode, thereafter the refresh signal AREF may be cyclically activated at desired internal timing. The refresh signal AREF may be used to control the timing of refresh operations during the refresh mode. A self-refresh exit command provided by controller 401 may cause the automatic activation of the refresh signal AREF to stop and may cause the device 400 to return to an idle state and/or resume other operations.

The refresh signal AREF is supplied to the refresh control circuit 416. Responsive, at least in part, to the refresh signal AREF, the refresh control circuit 416 supplies a refresh row address RXADD to the row decoder circuit 408 of the indicated bank, which may refresh one or more word lines WL indicated by the refresh row address RXADD. The refresh control circuit 416 may control a timing of the refresh operation and may generate and provide the refresh address RXADD. The refresh control circuit 416 may provide an automatic refresh address (e.g., from a sequence of auto refresh addresses) as the refresh address RXADD for a bank.

The automatic refresh addresses may be from a sequence of addresses which are provided based in part on activations of the refresh signal AREF. The refresh control circuit 416 may cycle through the sequence of auto refresh addresses. The refresh addresses RXADD may be a value provided by a CBR counter 428 or a based on the value provided by the CBR counter 428. Each value may correspond to a row address in some embodiments. The CBR counter 428 may have a number of bits that can represent a number of row addresses in a portion of the array 418 (e.g., rows per bank). For example, the CBR counter 428 may have seventeen bits in some embodiments. The CBR counter 428 may increment as described herein until it has cycled through all of the row addresses. After the CBR counter 428 has incremented through all of the values, it may reset and start counting from an initial value. In the example shown in FIG. 4, the CBR counter 428 is shared by all the banks of the memory array 418. Thus, the CBR counter 428 may be referred to as a global counter.

According to embodiments of the present disclosure, refresh logic 430 for a bank may receive the value of CBR counter 428 and a value from a bank increment counter (BIC) 432 for the bank. Based on the value of the CBR counter 228 and the value of the BIC 432, the refresh logic 430 may provide the refresh address RXADD for the bank. The value from the BIC 432 may indicate an amount the auto refresh addresses for the bank have incremented relative to the CBR counter 428 (e.g., offset from the CBR counter 428). Thus, the value of the BIC 432 may be referred to as an incremental value or incremental count. As used herein, “logic” refers to one or more circuits that implement one or more logical operations.

If the value of the BIC 432 is a certain value (e.g., 0), it may indicate the bank is in sync with the CBR counter 428, and the refresh logic 430 will output the value of the CBR counter 428 as RXADD. If the value of the BIC 432 is another value (e.g., non-zero), it may indicate the bank is out of sync with the CBR counter 428 (e.g., either ahead or behind). The refresh logic 430 may adjust the value provided by the CBR counter 428 based on the value of the BIC 432 and output the modified value as RXADD. For example, if the CBR counter 428 value is N, and the BIC 432 value is 1, it may indicate that the bank has already refreshed the row associated with the row address N. The refresh logic 430 may provide N+1 as RXADD. In this example, the row refreshed is offset from the row address N by the BIC 432 value (e.g., N+1).

In some embodiments, the CBR counter 428 may provide a flag signal to the BIC 432 to cause the BIC 432 to update its value (e.g., increase or decrease) as needed to maintain the relative offset from the CBR counter 428. In many memories, several rows are refreshed simultaneously, so some row address bits of RXADD are compressed. Thus, in some embodiments, instead of a separate signal, one or more of the bits provided by the CBR counter 428 may be used to signal the BIC 432 to update. In some embodiments, the bit may be provided from the refresh logic 430 rather than directly from the CBR counter 428.

In some embodiments, the BIC 432 may have a width of 2-4 bits. This may limit the amount a bank can fall out of sync with the CBR counter 428. The BIC 432 may provide incremental values and/or other signals to a count logic 434. The count logic 434 may cause the CBR counter 428 to increment based, at least in part, on the incremental values and/or signals provided from the BIC 432.

While FIG. 4 illustrates refresh logic 430 and BIC 432 of the banks as included in the refresh control circuit 416 in the peripheral area outside the memory banks of the memory array 418, in some embodiments, the refresh logic 430, BIC 432, and/or components thereof may be included in the logic areas of the individual banks (e.g., bank logic region).

In embodiments where the BIC 432 and/or refresh logic 430 are included with the banks, circuitry for row hammer mitigation may be shared/reused. For example, the row hammer mitigation circuitry may include adder circuits for calculating victim row addresses based on the aggressor row address. These adders can be reused by the refresh logic 430 during auto-refresh operations to add the value of the BIC 432 to the value of the CBR counter 428 to calculate the refresh row address RXADD.

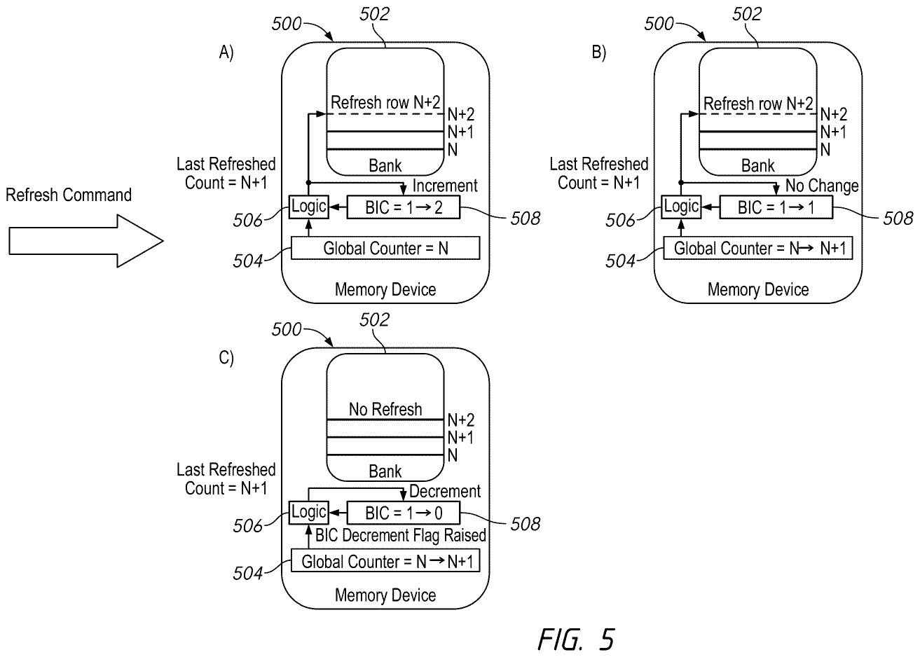

FIG. 5 shows block diagrams of a memory device illustrating behavior of a bank increment counter according to at least one embodiment of the disclosure. The drawings show a memory device 500 with a memory bank 502, a global counter 504 (CBR counter), refresh logic 506, and a bank increment counter (BIC) 508. In some embodiments, memory device 500 may be included in memory device 400, memory bank 502 may be included in any of BANKS0-15 of memory array 418. In some embodiments, global counter 504 may be included in CBR counter 428, refresh logic 506 may be included in refresh logic 430, and BIC 508 may be included in BIC 432.

In Scenario A, the global counter 504 provides a value N to the refresh logic 506. The BIC 508 has a value of 1 indicating the bank is one row ahead of the global counter 504. This means that the row refreshed during the previous refresh operation was N+1. Based on the value from the BIC 508, the refresh logic 506 modifies N to provide a row address of N+2, and row N+2 is refreshed as indicated by the dashed line. Further, the refresh logic 506 provides a signal to the BIC 508 to increment the value from 1 to 2. The signal may be one or more of the bits of the row address N+2 in some embodiments.

In Scenario B, the global counter 504 is incremented and provides a value N+1 to the refresh logic 506. The BIC 508 has a value of 1 indicating the bank is one row ahead of the global counter 504. This means that the row refreshed during the previous refresh operation was N+1. Based on the value from the BIC 508, the refresh logic 506 modifies N to provide a row address of N+2, and row N+2 is refreshed as indicated by the dashed line. Further, the refresh logic 506 provides a signal to the BIC 508. However, this signal indicates that the global counter 504 has been incremented and is now “catching up” to the BIC 508. Thus, the BIC 508 does not increment its value.

In Scenario C, the global counter 504 is incremented and provides a value N+1 to the refresh logic 506. The BIC 508 has a value of 1 indicating the bank is one row ahead of the global counter 504. This means that the row refreshed during the previous refresh operation was N+1. In contrast to Scenarios A and B, in Scenario C, no refresh command is received. Thus, no row is refreshed. The refresh logic 506 provides a signal to the BIC 508 to indicate the global counter 504 has been incremented. As in Scenario C, the global counter 504 is further “catching up” to the BIC 508. Since no refresh occurred, the BIC 508 decrements its value from 1 to 0 responsive to the signal from the refresh logic 506.

In summary, in the embodiment shown in FIG. 5, bank-specific refresh actions (e.g., REFpb/REFsb, or ACTL) may cause the BIC 508 value to increment by one. Any refresh commands (e.g., all bank refresh REFab or a final REFsb/pb for a bank group refresh) or other commands that cause the global counter 504 to increment may cause the BIC 508 to decrement by one.

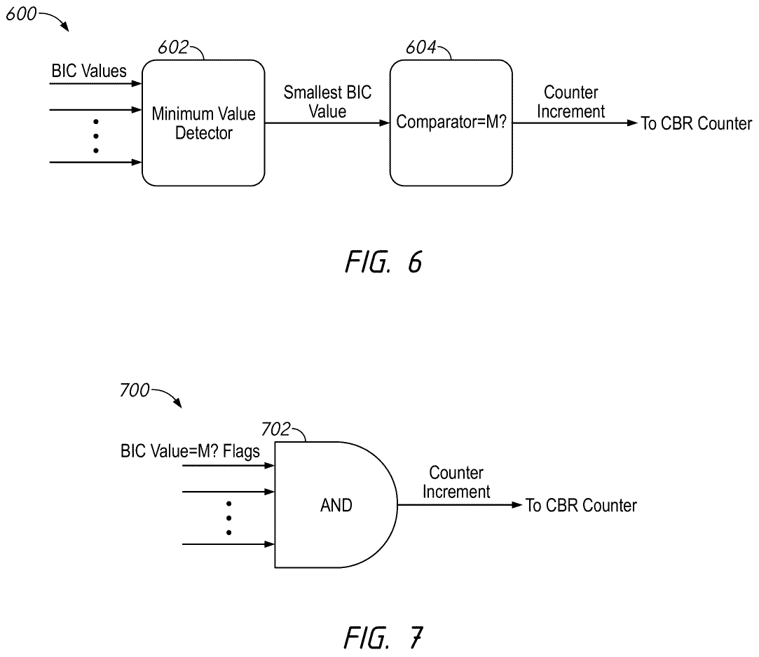

According to embodiments of the present disclosure, the count logic (e.g., count logic 434) may keep track of which banks are done refreshing such that the count logic can determine when to increment the global counter value. In some embodiments, the count logic may wait until all banks have performed M refreshes and then cause the global counter may increment its value by M. The threshold value M may be any non-zero positive integer. The incrementing of the global counter value may cause the BICs to decrement their values by M. In some embodiments, the count logic may poll the BICs and wait until the minimum BIC value is M. In some embodiments, each BIC may provide a signal (e.g., flag) to the count logic when the BIC's value reaches M. In some embodiments, the count logic may count M refresh commands, and then increment the global counter (e.g., CBR counter). FIGS. 6-8 illustrate example implementations of count logic.

FIG. 6 is a block diagram of count logic according to at least one embodiment of the disclosure. Count logic 600 may be used to implement count logic 434 in some embodiments. Count logic 600 may poll the BICs to determine when to increment the CBR counter (e.g., CBR counter 428, global counter 504).

Count logic 600 may include a minimum value detector circuit 602. The minimum value detector circuit 602 may receive the values from the BICs. The minimum value detector circuit 602 may compare the received values of the BICs and determine the smallest BIC value. The smallest value may be provided to a comparator circuit 604 of the count logic 600. The comparator circuit 604 may compare the smallest value to a value M (e.g., 1, 2, 3). When the smallest value is equal to or greater than M, the comparator circuit 604 may provide an active counter increment signal to the CBR counter. The activation of the counter increment signal may cause the CBR counter to increment its value by M. In some embodiments, this may also trigger the BICs to decrement their values by M.

FIG. 7 is a block diagram of count logic according to at least one embodiment of the disclosure. Count logic 700 may be used to implement count logic 434 in some embodiments. The BICs may include additional logic configured to provide an active signal (e.g., raise a flag) when the BIC value reaches M. Count logic 700 may analyze the signals from the BICs to determine when to increment the CBR counter (e.g., CBR counter 428, global counter 504).

In the example shown in FIG. 7, count logic 700 includes an AND logic circuit 702 to analyze the signals. When all of the signals are active (e.g., logic high, ‘1’), the AND logic circuit 702 provides an active counter increment signal to the CBR counter. The activation of the counter increment signal may cause the CBR counter to increment its value by M. In some embodiments, this may also trigger the BICs to decrement their values by M.

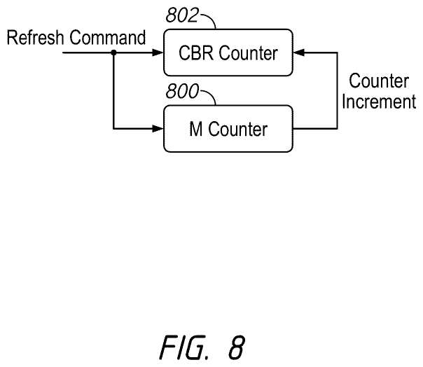

FIG. 8 is a block diagram of count logic and a CBR counter according to at least one embodiment of the disclosure. Count logic 800 may be used to implement count logic 434 in some embodiments. CBR counter may 802 may be included in the CBR counter 428 and/or global counter 504.

The count logic 800 includes a counter that counts to a value M. After reaching M, the count logic 800 may return to an initial value (e.g., 0). The count logic 800 may increment its value each time a refresh command (e.g., AREF) is received. When the count logic 800 reaches the value M, the count logic 800 provides an active counter increment signal to the CBR counter 802. The activation of the counter increment signal may cause the CBR counter 802 to increment its value by M. In some embodiments, this may also trigger the BICs to decrement their values by M.

While the embodiment shown in FIG. 8 reduces or eliminates the need for the count logic to receive signals from the BICs to increment the CBR counter, the embodiment shown in FIG. 8 may place a burden on the controller (e.g., controller 30 and/or controller 401) to keep track of the banks in a bank group that have been refreshed. Thus, in some applications, embodiments where the count logic receives signals from the BICs (such as the examples shown in FIGS. 6 and 7) may be preferrable.

As discussed with reference to FIG. 4, in some embodiments, the BICs may be located in a central location in the periphery of the memory. For example, in the periphery near the global (CBR) counter. In other embodiments, the BICs may be located in the bank logic of the individual banks. Locating the BICs in a central location may make it easier for the global counter to determine when to increment. This may be due in part to the information of all the BICs available near the global counter. However, locating the BICs in the bank logic may allow the row hammer circuitry (e.g., the adders) to be utilized for the refresh logic (e.g., refresh logic 430 and/or refresh logic 506), which may reduce overall layout costs.

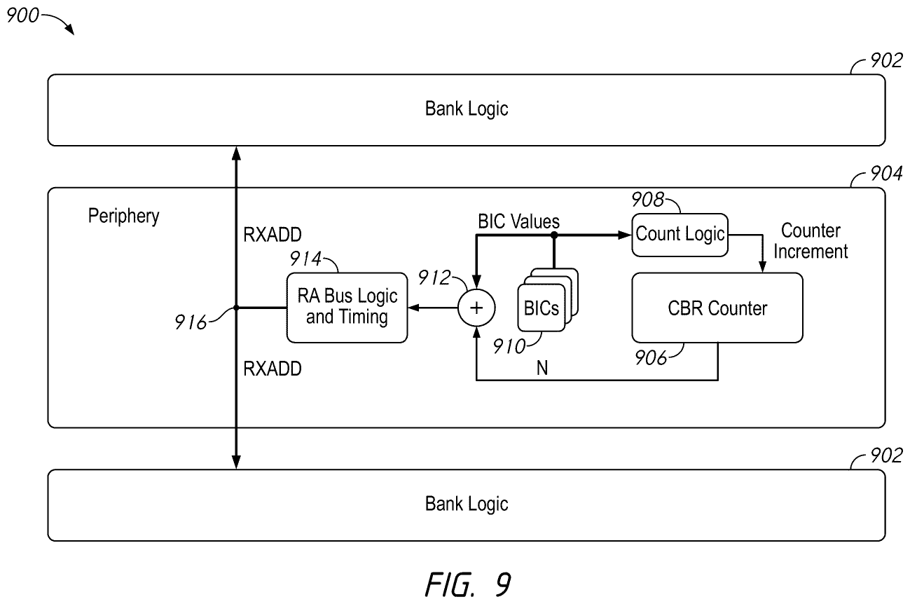

FIG. 9 is a block diagram of at least a portion of a memory device according at least one embodiment of the disclosure. Memory device 900 may be included in one or more of memories 310(0-p) and/or memory device 400 in some embodiments. Memory device 900 may include bank logic 902 associated with banks of a memory array (e.g., array 418) and a peripheral region (periphery) 904 outside the bank logic 902.

A (global) CBR counter 906, count logic 908, BICs 910, refresh logic 912, and row address (RA) bus logic and timing circuitry 914 may be located in the periphery 904. The CBR counter 906 may be included in CBR counter 802, global counter 504, and/or CBR counter 428. Count logic 908 may be included in count logic 800, 700, 600, and/or 434. BICs 910 may be included in BICs 508 and/or 432. The refresh logic 912 may be included in refresh logic 506 and/or 430.

The CBR counter 906 may provide a value N, which may correspond to an automatic refresh address to the refresh logic 912. The BICs 910 for the banks may provide their respective values to the refresh logic 912. The refresh logic 912 may include an adder and add the corresponding BIC value to the value N and provide a refresh address RXADD for each bank. The refresh addresses RXADD for the banks may be provided to the RA bus logic and timing circuitry 914 and then the RXADD are provided to the banks on the row address bus 916.

In this embodiment, the BICs 910 also provide their values or other signals to count logic 908. Count logic 908 may analyze the information from the BICs 910 to determine when the count logic 908 provides an active counter increment signal to the CBR counter 906. The counter increment signal may control the timing of when the value of the CBR counter 906 incremented. In some examples, the count logic 908 may be implemented as described in FIG. 6 or FIG. 7.

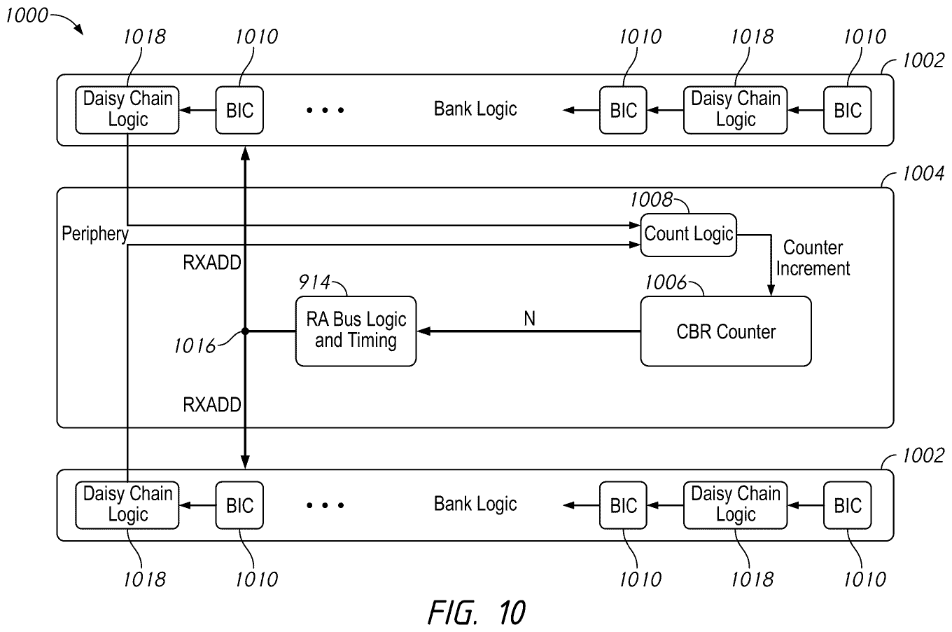

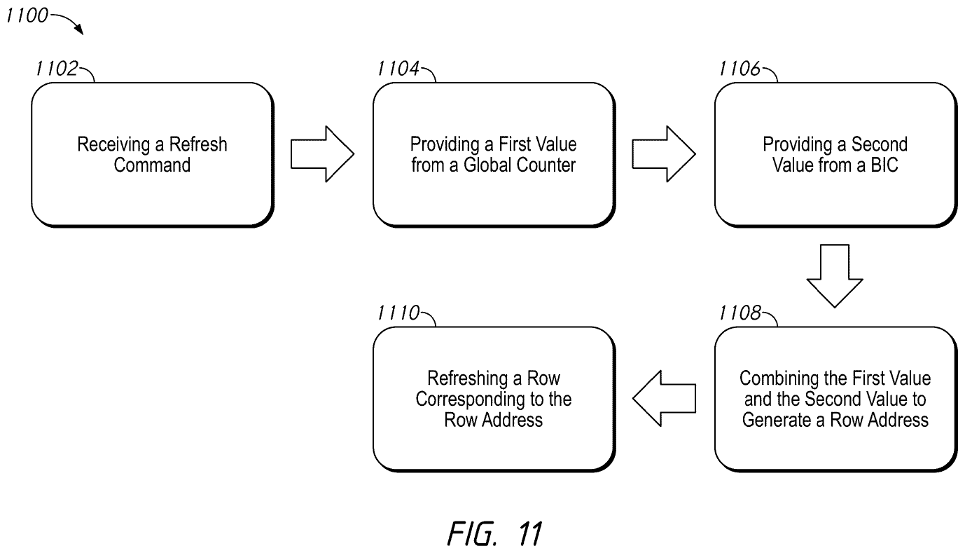

FIG. 10 is a block diagram of at least a portion of a memory device according at least one embodiment of the disclosure. Memory device 1000 may be included in one or more of memory devices 310(0-p) and/or memory device 400 in some embodiments. Memory device 900 may include bank logic 1002 associated with banks of a memory array (e.g., array 418) and a peripheral region (periphery) 1004 outside the bank logic 1002.

A (global) CBR counter 1006, count logic 1008, and row address (RA) bus logic and timing circuitry 1014 may be located in the periphery 1004. The CBR counter 1006 may be included in CBR counter 802, global counter 504, and/or CBR counter 428. Count logic 1008 may be included in count logic 800, 700, 600, and/or 434.

In contrast to FIG. 9, BICs 1010 for the banks are located in the bank logic 1002. The BICs 1010 may be included in BICs 508 and/or 432. The refresh logic (not shown in FIG. 10) may be included in the row hammer mitigation circuitry. In some embodiments, the adders for calculating the victim row addresses from the aggressor row address may be utilized as the refresh logic. The CBR counter 1006 may provide a value N, which may correspond to an automatic refresh address RXADD. The RA bus logic and timing circuitry 1014 may provide the RXADD on the row address bus 1016 to the bank logic of the banks. The adders for the banks may add the values of the BICs 1010 to the RXADD to determine the row address for the row to be refreshed for the individual banks.

The bank logic 1002 may further include daisy chain logic 1018 in some embodiments. Individual banks may send a signal to its neighbor bank(s) via the daisy chain logic 1018. In some embodiments, the signal may be a flag that a BIC value has reached M. In other embodiments, the signal may be the value of the BIC. The daisy chain logic 1018 may provide a signal to the next bank's logic. The daisy chain logic 1018 may include one or more circuits that combine the information from the previous banks. For example, the daisy chain logic 1018 may include an AND logic circuit when the signal from the BICs are flags that the BIC value has reached M. In another example, the daisy chain logic 1018 may include a minimum value detector when the signal includes the BIC values. A signal from the daisy chain logic 1018 of the final bank may be provided to count logic 1008. Count logic 1008 may analyze the information from the daisy chain logic 1018 to determine when the count logic 1008 provides an active counter increment signal to the CBR counter 1006. The counter increment signal may control the timing of when the value of the CBR counter 1006 incremented. In some examples, the count logic 1008 may be implemented as described in FIG. 6 or FIG. 7. In some examples, some of the components of the count logic 1008 may be included in the daisy chain logic 1018 and the remaining portion(s) may be included in the count logic 1008. Alternatively, if the embodiment shown in FIG. 8 is used to implement the count logic 1008, the daisy chain logic 1018 may be omitted.

FIG. 11 is a flow chart of a method according to at least one embodiment of the disclosure. In some embodiments, the method shown in flow chart 1100 may be performed by a memory device such as any of memories 310(0-p), memory device 400, memory device 900, and/or memory device 1000 in some embodiments.

At block 1102, “receiving a refresh command” may be performed. At block 1104, “providing a first value from a global counter” may be performed. For example, CBR counter 428. At block 1106, “providing a second value from a BIC” may be performed. For example, BIC 432. At block 1108, “combining the first value and the second value to generate a row address” may be performed. This may be performed by refresh logic, such as refresh logic 430. In some embodiments, combining the first value and the second value comprises adding the first value and the second value. At block 1110 “refreshing a row corresponding to the row address” may be performed. For example, based on the row address, the row decoder circuit 408 may cause the row to be refreshed.

In some embodiments, at least one bit of the first value, the row address, or a combination thereof may be used as a flag to determine when to increment the value of the BIC. In these embodiments, the method shown in flow chart 1100 may further include incrementing the second value based, at least in part, on at least one bit of the first value, the row address, or a combination thereof. In some embodiments, the flag may be provided by the refresh logic to the BIC.

In some embodiments, the method shown in flow chart 1100 may further include incrementing the first value. In some embodiments, incrementing the first value is responsive to the second value reaching a threshold value. In some embodiments, incrementing the first value is responsive to a number of refresh commands received reaching a threshold value. In some embodiments, the method shown in flow chart 1100 further includes decrementing the second value responsive to the incrementing of the first value.

The systems, apparatuses, and methods disclosed herein may allow banks of a bank group to refresh out of sync. The banks may refresh a different row if an extra refresh command is received. Allowing the banks to refresh out of sync may reduce “wasted” refresh commands and/or reduce the risk of skipping rows during refresh operations.

Any one of the examples, embodiments or processes described herein may be combined with one or more other examples, embodiments and/or processes or be separated and/or performed amongst separate devices or device portions in accordance with the present systems, apparatuses, and methods.

The present description of certain embodiments is merely exemplary in nature and is in no way intended to limit the scope of the disclosure or its applications or uses. In the detailed description of embodiments of the present apparatuses, systems and methods, reference is made to the accompanying drawings which form a part hereof, and which are shown by way of illustration specific embodiments in which the described apparatuses, systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features are not be discussed when they would be apparent to those with skill in the art so as not to obscure the description of embodiments of the disclosure.

Finally, the above-discussion is intended to be merely illustrative of the present apparatuses, systems, and methods, and should not be construed as limiting the appended claims to any particular embodiment or group of embodiments. Thus, while the present apparatuses, systems, and methods have been described in particular detail with reference to exemplary embodiments, it should also be appreciated that numerous modifications and alternative embodiments may be devised by those having ordinary skill in the art without departing from the broader and intended spirit and scope of the present apparatuses, systems, and methods as set forth in the claims that follow. Accordingly, the specification and drawings are to be regarded in an illustrative manner and are not intended to limit the scope of the appended claims.

What is claimed is:

1. An apparatus comprising:
a memory array comprising a bank;
a global counter configured to provide a first value;
a bank increment counter (BIC) associated with the bank configured to provide a second value; and
refresh logic configured to modify the first value based on the second value to provide a row address to be refreshed in the bank.

2. The apparatus of claim 1, wherein the second value indicates an increment of the BIC relative to an increment of the global counter.

3. The apparatus of claim 1, wherein the refresh logic comprises an adder configured to add the first value and the second value to provide the row address.

4. The apparatus of claim 1, further comprising row hammer mitigation circuits, wherein the refresh logic includes at least one circuit of the row hammer mitigation circuits.

5. The apparatus of claim 1, wherein the global counter, the BIC, and the refresh logic are located in a peripheral region.

6. The apparatus of claim 1, further comprising count logic configured to provide a signal to the global counter to determine when the global counter increments.

7. The apparatus of claim 6, wherein the BIC and the refresh logic are located in a bank logic region of the bank, and the global counter and the count logic are located in a peripheral region.

8. The apparatus of claim 7, further comprising daisy chain logic in the bank logic region of the bank, wherein the daisy chain logic is configured to receive, provide, or a combination thereof, information from a second bank.

9. The apparatus of claim 8, wherein the information includes a value from a second BIC or a flag from the second BIC.

10. The apparatus of claim 1, wherein the BIC comprises two, three, or four bits.

11. A memory device comprising:
a memory array comprising a plurality of banks;
a global counter configured to provide a first value corresponding to an automatic refresh address;
a plurality of bank increment counters (BICs) associated with corresponding ones of the plurality of banks, each configured to provide a second value; and
a plurality of refresh logics associated with corresponding ones of the plurality of banks, each configured to modify the first value based on the second value to provide a row address to be refreshed in a bank of the plurality of banks.

12. The memory device of claim 11, wherein a bit of the first value indicates when the global counter increments the first value, and wherein the plurality of BICs are configured to adjust the second value based on the bit.

13. The memory device of claim 11, further comprising count logic provide a signal to the global counter to determine when the global counter increments.

14. The memory device of claim 13, wherein the count logic includes a counter configured to count a number of refresh commands received and activate the signal when the number of refresh commands reaches a threshold value.

15. The memory device of claim 13, wherein the count logic comprises a minimum value detector and a comparator,
wherein the minimum value detector is configured to receive the second values from the plurality of BICs and provide a minimum value of the second values, and
wherein the comparator is configured to compare the minimum value to a threshold value and activate the signal when the minimum value is equal to or greater than the threshold value.

16. The memory device of claim 13, wherein the count logic comprises an AND logic circuit configured to receive a plurality of flags from the plurality of BICs, wherein the plurality of flags indicate whether corresponding ones of the plurality of BICs have reached a threshold value, wherein the AND logic circuit is configured to activate the signal when the plurality of flags are logic high.

17. A method comprising:
receiving a refresh command;
providing a first value from a global counter;
providing a second value from a bank increment counter (BIC);
combining the first value and the second value to generate a row address; and
refreshing a row corresponding to the row address.

18. The method of claim 17, further comprising incrementing the second value based, at least in part, on at least one bit of the first value, the row address, or a combination thereof.

19. The method of claim 17, further comprising incrementing the first value.

20. The method of claim 19, further comprising decrementing the second value responsive to the incrementing of the first value.

21. The method of claim 19, wherein incrementing the first value is responsive to the second value reaching a threshold value.

22. The method of claim 19, wherein incrementing the first value is responsive to a number of refresh commands received reaching a threshold value.

23. The method of claim 17, wherein combining the first value and the second value comprises adding the first value and the second value.
